(19) United States
(12) Patent Application Publication
(10) Pub. No.: US 2012/0316804 A1
(43) Pub. Date: Dec. 13, 2012

(54) TECHNIQUE FOR ARC DETECTION IN PHOTOVOLTAIC SYSTEMS AND OTHER SYSTEMS

(75) Inventor: Christopher A. Oberhauser, San Jose, CA (US)

(73) Assignee: Texas Instruments Incorporated, Dallas, TX (US)

(21) Appl. No.: 13/490,315

(22) Filed: Jun. 6, 2012

Related U.S. Application Data
(60) Provisional application No. 61/494,285, filed on Jun. 7, 2011.

(51) Int. Cl. G06F 19/00; G01R 31/08

(52) U.S. Cl. 702/58

(57) ABSTRACT

A method includes receiving data associated with operation of a high-voltage system, determining a power spectrum associated with the data, and dividing the power spectrum into multiple bands. The method also includes filtering one or more interfering signals from the power spectrum within the bands and generating an arc detection result indicative of whether an electrical arc is present in the high-voltage system using remaining signals within the bands. Filtering the interfering signal(s) could include identifying one or more peak values at one or more frequencies in each of the bands and at least partially reducing a magnitude of the power spectrum at each of the one or more frequencies in each of the bands. The arc detection result can be generated by summing magnitudes of the remaining signals in each of the bands and applying at least one scaling factor to at least one of the summations.

### CROSS-REFERENCE TO RELATED APPLICATION AND PRIORITY CLAIM

This application claims priority under 35 U.S.C. §119(e) to U.S. Provisional Patent Application No. 61/494,285 filed on Jun. 7, 2011, which is hereby incorporated by reference.

### TECHNICAL FIELD

This disclosure relates generally to photovoltaic systems and other high-voltage systems. More specifically, this disclosure relates to a technique for arc detection in photovoltaic systems and other systems.

### BACKGROUND

Photovoltaic panels (solar panels) are routinely used to convert sunlight into electrical energy. In many photovoltaic systems, large arrays of photovoltaic panels are used to generate electrical energy. For example, an array could include a number of photovoltaic panels coupled in series to form a string, and multiple strings can be coupled in parallel.

In these types of systems, high voltages can be generated using the photovoltaic panels, and electrical arcs can form within the systems. Electrical arcs are a clear safety hazard and can cause fires or other problems within a photovoltaic system. However, detecting electrical arcs in these types of systems can be problematic for a variety of reasons. One reason is that a large amount of noise can be present in signals obtained from a photovoltaic system.

### SUMMARY

This disclosure provides a technique for arc detection in photovoltaic systems and other systems.

In a first embodiment, a method includes receiving data associated with operation of a high-voltage system, determining a power spectrum associated with the data, and dividing the power spectrum into multiple bands. The method also includes filtering one or more interfering signals from the power spectrum within the bands and generating an arc detection result indicative of whether an electrical arc is present in the high-voltage system using remaining signals within the bands.

In a second embodiment, an apparatus includes at least one interface configured to receive data associated with operation of a high-voltage system. The apparatus also includes at least one processing unit configured to determine a power spectrum associated with the data, divide the power spectrum into multiple bands, filter one or more interfering signals from the power spectrum within the bands, and generate an arc detection result indicative of whether an electrical arc is present in the high-voltage system using remaining signals within the bands.

In a third embodiment, a non-transitory computer readable medium embodies a computer program. The computer program includes computer readable program code for receiving data associated with operation of a high-voltage system, for determining a power spectrum associated with the data, and for dividing the power spectrum into multiple bands. The computer program also includes computer readable program code for filtering one or more interfering signals from the power spectrum within the bands and for generating an arc detection result indicative of whether an electrical arc is present in the high-voltage system using remaining signals within the bands.

Other technical features may be readily apparent to one skilled in the art from the following figures, descriptions, and claims.

### BRIEF DESCRIPTION OF THE DRAWINGS

For a more complete understanding of this disclosure and its features, reference is now made to the following description, taken in conjunction with the accompanying drawings, in which:

FIG. 1 illustrates an example photovoltaic system with an arc detector in accordance with this disclosure;

FIG. 2 illustrates an example method for arc detection in accordance with this disclosure;

FIGS. 3 and 4 illustrate example signals associated with arcing and non-arcing conditions in accordance with this disclosure;

FIGS. 5 through 9 illustrate example implementations of various steps in the method of FIG. 2 in accordance with this disclosure; and

FIGS. 10 through 13 illustrate an example circuit board implementing an arc detector and related details in accordance with this disclosure.

### DETAILED DESCRIPTION

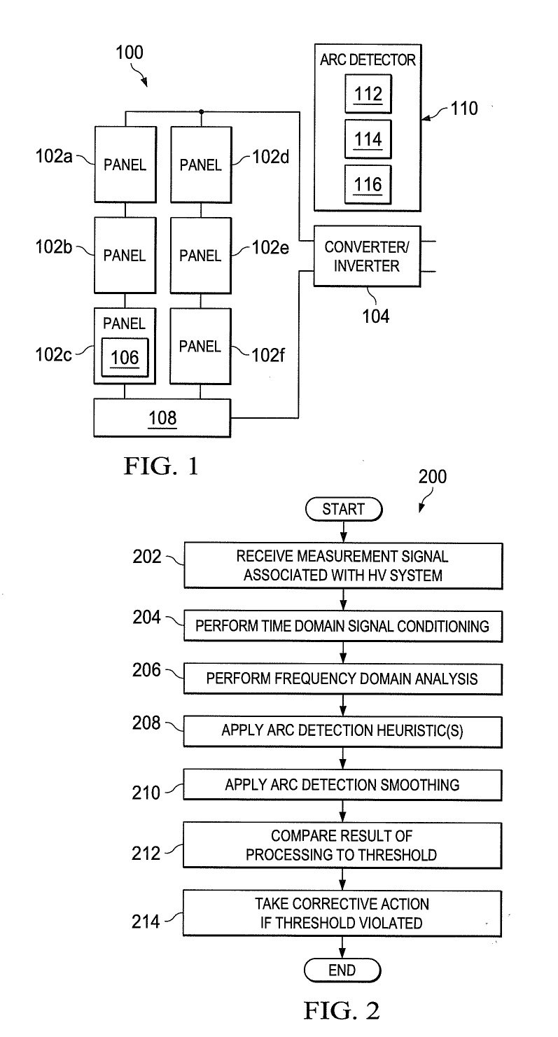

FIGS. 1 through 13 discussed below and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

FIG. 1 illustrates an example photovoltaic system 100 with an arc detector in accordance with this disclosure. As shown in FIG. 1, the system 100 includes an array of photovoltaic (PV) panels 102a-102f coupled to a power converter/inverter 104. The PV panels 102a-102f in the array are arranged in strings. In this example, the array includes two strings, each with three PV panels. However, an array may include any number of strings, and each string may include any number of PV panels. Each PV panel includes any suitable structure(s) for converting solar energy into electrical energy.

The power converter/inverter 104 converts power generated by the PV panels 102a-102f into a form more suitable for a particular application. In some embodiments, the power converter/inverter 104 includes an inverter or a direct current-to-alternating current (DC-to-AC) converter that converts DC power from the PV panels 102a-102f into an AC signal. This may allow the system 100 to provide power over an AC distribution grid. In other embodiments, the power converter/inverter 104 includes a DC-to-DC converter that converts DC power from the PV panels 102a-102f into a different DC voltage. This may allow the system 100 to provide power to a particular load that requires DC power in a specific form.

In this example, various other devices could be included within the system 100. For example, each PV panel or group of PV panels could be associated with a junction box 106, which may contain various components used during operation of the PV panel(s). For instance, the junction box 106 could include a power controller, which could perform maximum power point tracking (MPPT) or other functions for the PV panel(s). Also, a combiner 108 could be used to combine power from multiple strings into a single output provided to the power converter/inverter 104. The combiner 108 could control the combination in order to provide a maximum amount of power to the power converter/inverter 104. Any other or additional components could be used within the system 100.

As shown in FIG. 1, the system 100 includes at least one arc detector 110. As described in more detail below, the arc detector 110 performs various functions (such as signal analysis functions) to detect the presence of electrical arcs within the system 100. In response to a detected arc, the arc detector 110 could take any suitable action, such as triggering an alarm or automatically shutting down at least a portion of the system 100.

The arc detector 110 includes any suitable structure for detecting electrical arcs. For example, the arc detector 110 could be implemented using hardware only or a combination of hardware and software/firmware instructions. In this example, the arc detector 110 is implemented using at least one memory unit 112, at least one processing unit 114, and at least one communication interface 116. The at least one memory unit 112 includes any suitable volatile and/or non-volatile storage and retrieval device(s), such as a hard disk, solid state memory, optical storage disc, RAM, or ROM. The at least one processing unit 114 includes any suitable processing structure(s), such as a microprocessor, microcontroller, digital signal processor, application specific integrated circuit, or field programmable gate array. The at least one communication interface 116 includes any suitable structure(s) for transmitting and/or receiving data over one or more communication lines or networks. This represents one specific way in which the arc detector 110 can be implemented, and other implementations of the arc detector 110 could be used. When implemented using software and/or firmware, the arc detector 110 may include any suitable program instructions that analyze signals to detect electrical arcs.

Note that a single arc detector 110 could be used to detect electrical arcs in a single PV string or in multiple PV strings in a PV system 100. In some embodiments, a single arc detector 110 could be used to detect electrical arcs in up to four PV strings. In particular embodiments, the arc detector 110 supports one or multiple sets of data structures, where each set of data structures is associated with a different PV string. When used outside of a PV system, a single arc detector 110 could be used to detect electrical arcs in a single portion of a system or in multiple portions of the system.

Also note that the arc detector 110 could be compliant with one or more electrical or other standards. For example, in some embodiments, the arc detector 110 could comply with the appropriate 2011 National Electrical Code (NEC) standard.

Although FIG. 1 illustrates one example of a photovoltaic system 100 with an arc detector 110, various changes may be made to FIG. 1. For example, as noted above, the number and arrangement of PV panels in FIG. 1 is for illustration only. Also, the functional division shown in FIG. 1 is for illustration only. Various components in FIG. 1 could be combined, further subdivided, or omitted and additional components could be added according to particular needs. For instance, an arc detector 110 could be incorporated into each junction box 106 or other component(s) of the system 100. Further, any number of arc detectors 110 could be used in any suitable location(s) of the system 100. In addition, the arc detector 110 could be used in any suitable high-voltage system and is not limited to use in just photovoltaic systems. A “high-voltage” system refers to any system that generates adequate voltage to create electrical arcs. Other example uses of the arc detector 110 include AC fault detection and the detection of arcs in electrolysis systems.

FIG. 2 illustrates an example method 200 for arc detection in accordance with this disclosure. The method 200 could, for example, be used by the arc detector 110 in the PV system 100 of FIG. 1. However, the method 200 could be used by any other suitable arc detection device and in any other suitable system.

As shown in FIG. 2, at least one measurement signal associated with a high-voltage (HV) system is received at step 202. This could include, for example, the arc detector 110 receiving a signal containing measurements of the current flowing through a PV string (referred to as the “string current”).

Time domain signal conditioning is performed at step 204. This could include, for example, the arc detector 110 applying analog filtering to the measurement signal. Any suitable time domain signal conditioning could be used to condition a measurement signal. As particular examples, a range and an average of the measurement signal could be calculated, and a Hanning window could be applied to the measurement signal.

Frequency domain analysis is performed at step 206, and one or more arc detection heuristics are applied at step 208. This could include, for example, the arc detector 110 converting the conditioned time domain signal into the frequency domain, such as by using a fast Fourier transform (FFT). Once in the frequency domain, any suitable frequency domain analysis and arc detection heuristics could be used to identify information about possible electrical arcs. As particular examples, results generated using the FFT could be converted into a power spectrum, the spectral region of the frequency domain signal could be divided into different bands, and interfering (jamming) signals can be removed from each band. Various other signal processing operations (such as dynamic scaling and the application of a device-specific calibration factor) can be applied, and a resulting value may be used as an indication of whether or not an arc appears to be present in the high-voltage system.

Arc detection smoothing is applied at step 210. This can be done to reduce or avoid false positives (false indications that an arc is present). Any suitable technique for arc detection smoothing could be used, such as by averaging multiple resulting values obtained by the steps 202-208.

The final result of the processing in steps 202-210 is compared to a threshold at step 212. The threshold could be selected to differentiate between “no arc” conditions and “arc” conditions. Corrective action can then be taken if the threshold is violated at step 214. This could include, for example, the arc detector 110 triggering an alarm, shutting down at least a portion of the high-voltage system, or performing some other function(s).

Although FIG. 2 illustrates one example of a method 200 for arc detection, various changes may be made to FIG. 2. For example, while shown as a series of steps, various steps in FIG. 2 could overlap, occur in parallel, occur in a different order, or occur multiple times. Also, as noted above, while described with respect to the PV system 100 of FIG. 1, the method 200 could be used with any other high-voltage system that can generate electrical arcs. In addition, as noted above, the arc detector 110 could be used with multiple PV strings or other portions of a system. In these embodiments, the arc detector 110 could perform the method 200 for each PV string or other portion of the system.

The remaining figures and discussions below describe specific implementations of the arc detector 110, as well as example signals that could be analyzed by the arc detector 110. These details are for illustration only and do not limit the scope of this disclosure.

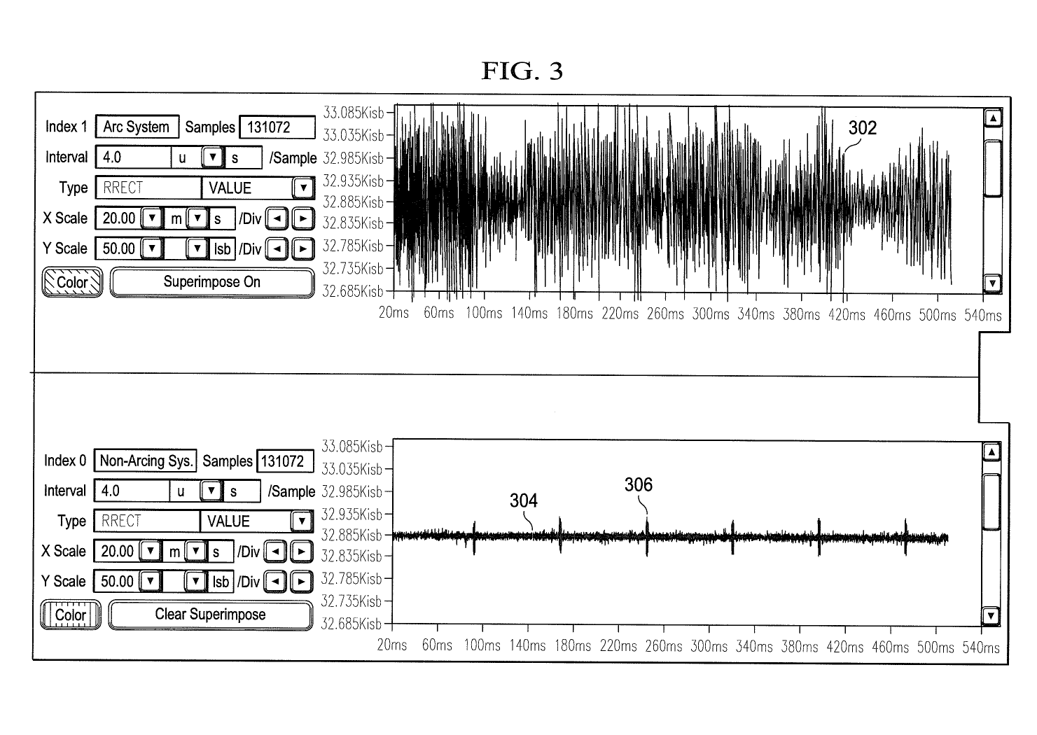

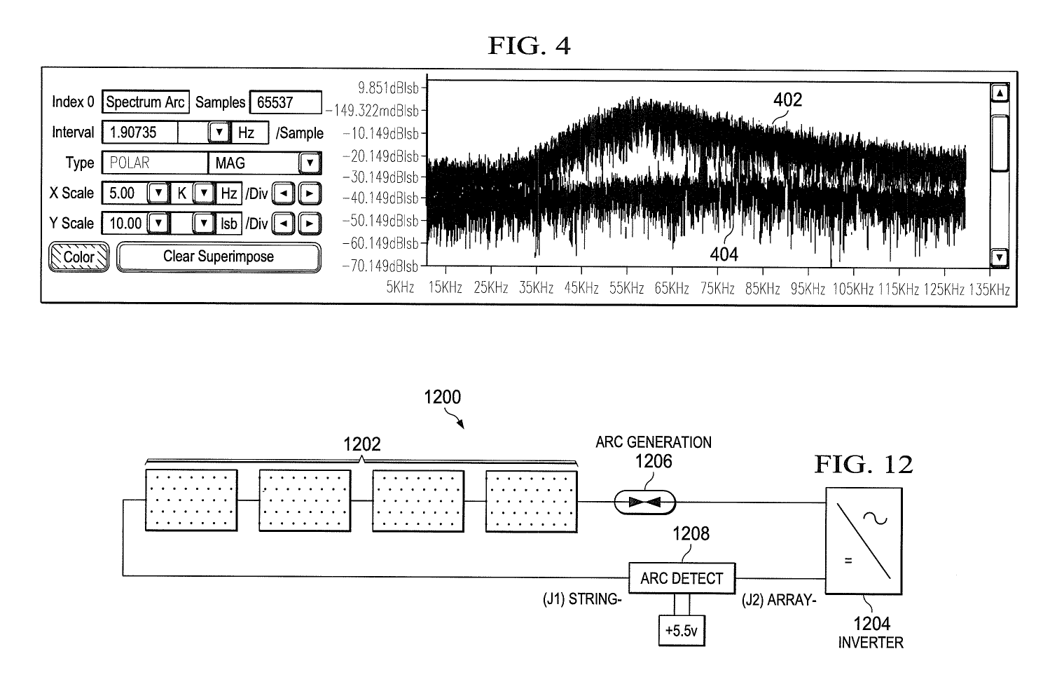

FIGS. 3 and 4 illustrate example signals associated with arcing and non-arcing conditions in accordance with this disclosure. FIG. 3 illustrates example time domain signals 302 and 304 associated with arcing and non-arcing conditions, respectively. In FIG. 3, the signal 302 represents an arcing signal (a signal captured during an electrical arc), and the signal 304 represents a non-arcing signal (a signal captured during no electrical arc). These signals 302-304 already have analog signal processing applied. In the non-arcing signal 304, there are periodic interfering signals 306, which could be caused by any interfering source. These time domain signals 302-304 can be further processed to identify arcing and non-arcing conditions.

FIG. 4 illustrates the signals 302-304 of FIG. 3 converted into frequency domain signals 402-404, respectively. The arcing signal 302 is represented in the frequency domain by signal 402, and the non-arcing signal is represented in the frequency domain by signal 404.

FIGS. 3 and 4 illustrate that there can be a tradeoff between the frequencies used to detect electrical arcs. Overall, an arcing signal (which looks like noise) is higher in amplitude at lower frequencies and rolls off at higher frequencies. The FCC limits interference at higher frequencies (such as in the MHz range), but not as much at lower frequencies. Also, very low frequencies have limits in coupling and are “slower” to change in a time sense. With this in mind, within a lower frequency band (such as between about 1 kHz to about 90 kHz in this example), less power may be required by the arc detector 110 to detect an electrical arc since the difference between arc and non-arc conditions is more pronounced, but there is potentially more interference at lower frequencies. With a higher frequency band (such as about 100 kHz to about 200 kHz in this example), there is typically less noise, but more power is required to identify electrical arcs since the difference between arc and non-arc conditions is less pronounced. Note that the specific frequency bands given here are examples only. Other frequency bands could also be used without departing from the scope of this disclosure.

Note that FIGS. 3 and 4 illustrate characteristics of a “well-behaved” system in which it is quite easy to differentiate between arcing and non-arcing conditions. Other systems may experience more noise or other problems, making it more difficult to clearly identify when electrical arcs occur.

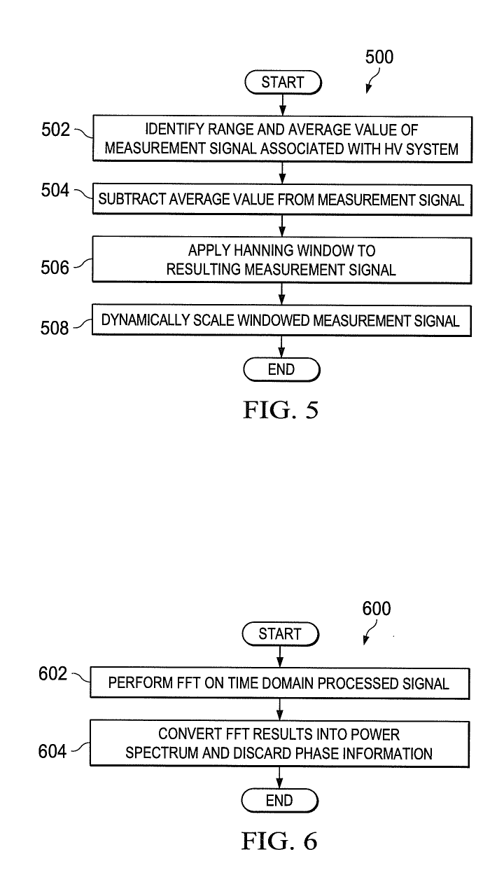

FIGS. 5 through 9 illustrate example implementations of various steps in the method 200 of FIG. 2 in accordance with this disclosure. Among other uses, these implementations of the steps in FIG. 2 can be used with “less-behaved” systems where it may be more difficult to differentiate between arcing and non-arcing conditions. Note that the following describes a particular implementation of the method 200 for detecting electrical arcs. Other embodiments of the method 200 could be used, and one, some, or all of the features described below could be used within the method 200 of FIG. 2.

The seven parameters in Table 1 can be used during the arc detection routine described in FIGS. 5 through 9.

TABLE 1

| Parameter | Function |
|---|---|
| Min Frequency | The minimum frequency that the arc detector |
| | 110 includes in a summation. |
| Max Frequency | The maximum frequency that the arc detector |
| | 110 includes in the summation. All spectral |
| | power between the minimum and maximum |
| | frequencies are potentially included in the |
| | summation. Alternatively, instead of Max |
| | Frequency, a Bandwidth parameter (which when |
| | summed with the Min Frequency produces the |
| | Max Frequency) can be used. |
| Discard Factor | The portion of each spectral band that is |
| | removed prior to summation. |
| Filter Weight | A scaling factor applied to a frequency band. |
| | The scaling factor can be applied per band, |
| | and in some implementations it may only be |
| | applied to one or an arbitrary number of |
| | bands. |
| Clipping Level | A maximum allowable single measurement, which |
| | can be used to minimize false tripping. |
| Threshold | A measurement score above which there is |
| | considered to be an active arcing condition. |
| Calibration | A per-unit adjustment to the power level, |
| Offset | which is used to correct for individual |
| | device variations. |
| Number of Bands | The number of frequency bands used to divide |
| | the spectrum between Min Frequency and Max |
| | Frequency into analysis regions. In some |
| | implementations, this can be hard-coded to a |
| | value of two. |

Step 204 of FIG. 2 could occur as shown in FIG. 5, which illustrates an example method 500 for time domain signal conditioning. As shown in FIG. 5, the range and the average value of an input measurement signal are calculated at step 502. This could include, for example, the arc detector 110 processing the measurement signal received at step 202 of FIG. 2. The average value is subtracted from the measurement signal at step 504, and a Hanning window is applied to the resulting measurement signal at step 506. This could include, for example, the arc detector 110 applying the Hanning window to help preserve the noise floor better than other windows in the presence of high-amplitude signals. This could also include the arc detector 110 smearing the resulting measurement signal into ¾ bins spectrally. The windowed measurement signal is dynamically scaled at step 508. This could include, for example, the arc detector 110 taking the windowed measurement signal and dynamically scaling the signal based on the calculated range to approximately ¼ of the full-scale range. The signal can be gained up here to more effectively use the dynamic range of DSP calculations (or other calculations), and it may be needed due to Hanning window multiplication. In addition, a subsequent FFT may have a limited input range (such as ±0.5).

Step 206 of FIG. 2 could occur as shown in FIG. 6, which illustrates an example method 600 for frequency domain analysis. As shown in FIG. 6, an FFT is performed on the time domain processed signal at step 602. This could include, for example, the arc detector 110 performing a DSP-provided routine or other routine. In particular embodiments, the FFT could involve the use of 1,024 samples with a “power of two” FFT. The calculations can be done in-place to save memory, and a complex time domain signal may be the input here. A 16-bit FFT could be performed (i.e. Q15 fixed point) instead of a 32-bit FFT since the 16-bit FFT is faster, and care can be taken to ensure that dynamic range is not lost. Note, however, that 32-bit or other FFT schemes could be used. Also note that other transformations could be used to convert a time domain signal into a frequency domain signal.

The complex results of the FFT are converted into a power spectrum and phase information is discarded at step 604. This could include, for example, the arc detector 110 using long (32-bit) values as the data type for the spectral magnitude, which can be used to minimize rounding errors. Here, only the relevant portion of the power spectrum (defined between Min Frequency and Max Frequency) may be calculated, which can reduce power consumption and computational time by not calculating unused frequencies. Moreover, magnitude calculations for generating the power spectrum may represent “magnitude squared” values, since a subsequent summation may use magnitude squared values and this saves a computational intensive step.

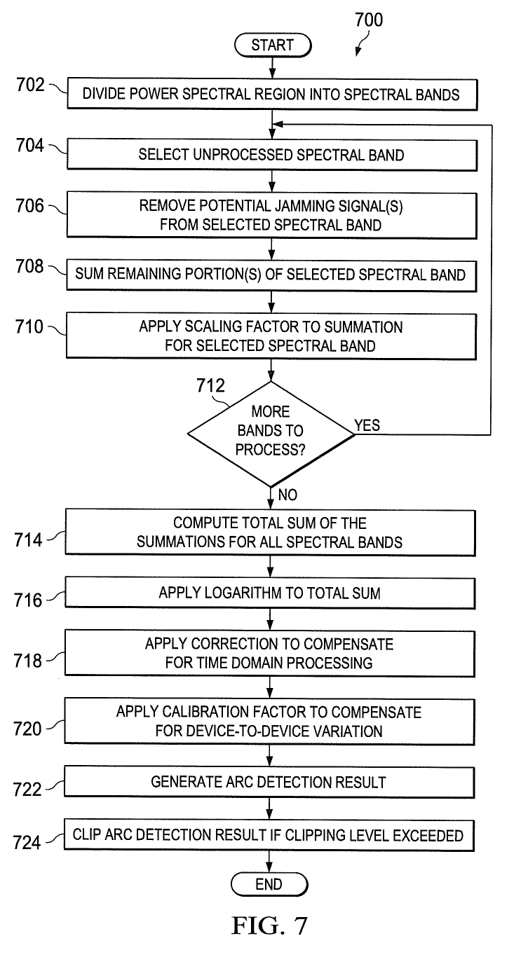

Step 208 of FIG. 2 could occur as shown in FIG. 7, which illustrates an example method 700 for applying arc detection heuristic(s). As shown in FIG. 7, the spectral region in the power domain is divided into multiple spectral bands at step 702. This could include, for example, the arc detector 110 dividing the power spectral region (between Min Frequency and Max Frequency) into evenly-sized bands. This allows for handling shifts in the noise floor across frequency. In some embodiments, two spectral bands are used, although any other number of bands could be used.

An unprocessed spectral band is selected at step 704. This could include, for example, the arc detector 110 selecting the lowest-frequency band, the highest-frequency band, or some other unprocessed band. For the selected spectral band, potential jamming signals are removed from the selected band at step 706. The following operations can be repeated during step 706 according to the value of Discard Factor. First, a potential jammer is considered the peak value in the spectral band being processed, as a jammer that is not above the overall average noise floor may not present an issue. Second, the removal of the potential jammer is performed by reducing the value of the magnitude squared spectrum at the frequency of the jammer. The reduction can be to zero or to a minimum value in the spectrum. In some embodiments, the range of the Discard Factor could be from 0% to 70%. If 512-point FFT is used, with some frequency settings, about 102 bins of relevant spectral information may be present, so discarding 20% means 20 bins are removed. Assuming jammers are present and are “smeared” into four bins from the Hanning window, this means that up to five jammers can be suppressed.

After removal of the potential jammer(s) in the selected band, the remaining portion(s) of the spectrum in the selected band is (are) summed at step 708. This could include, for example, the arc detector 110 summing the magnitude-squared spectrum in the selected band and converting the sum to floating point. Note that the “remaining portion(s)” of the spectrum in the selected band may or may not include the potential jammer(s). If the magnitude of a potential jammer is reduced but not zeroed, its value may or may not be used in summing the magnitudes in the selected band. An appropriate scaling factor is applied to the summation for the selected band at step 710. This could include, for example, the arc detector 110 applying the Filter Weight parameter to the sum. Each band could have its own Filter Weight, but a single Filter Weight is acceptable when only two bands are used.

A determination is made whether any spectral bands remain to be processed at step 712. If so, the method 700 returns to step 704 to select another spectral band. In this way, steps 704-710 are performed for each spectral band in the power spectral region created in step 702.

A total sum of the summations for the spectral bands is computed at step 714. This could include, for example, the arc detector 110 summing the scaled values generated in step 710 for all spectral bands. A logarithm is taken of the total sum at step 716. A correction is made to the logarithmic value to compensate for the time domain processing at step 718. This could include, for example, the arc detector 110 applying a correction to compensate for dynamic scaling applied in the time domain processing. A calibration factor may be applied to the logarithmic value to compensate for device-to-device variations at step 720. This could include, for example, the arc detector 110 applying the Calibration Offset parameter to the logarithmic value of the total sum.

An arc detection result is generated at step 722. The arc detection result could represent the processed and corrected total sum produced in steps 714-720. In some embodiments, a no-arc condition could result in a value around 68 while an arc condition could result in a value around 90 (using a natural logarithm). Since these are logarithmic values, a value of 90 represents an increase of about 150 times the no-arc level at a value of 68. In other embodiments, a no-arc condition could result in a value around 5 to 10 while an arc condition could result in a value around 40 (using a log₁₀ function). A value of 40 represents an increase of about 60 times the no-arc level at a value of 5. If the arc detection result exceeds a clipping level, the arc detection result is clipped at step 724. This could include, for example, the arc detector 110 determining whether the arc detection result exceeds the Clipping Level parameter and, if so, setting the arc detection result to the Clipping Level parameter value. Among other things, the clipping can be used to limit spurious false arc detections.

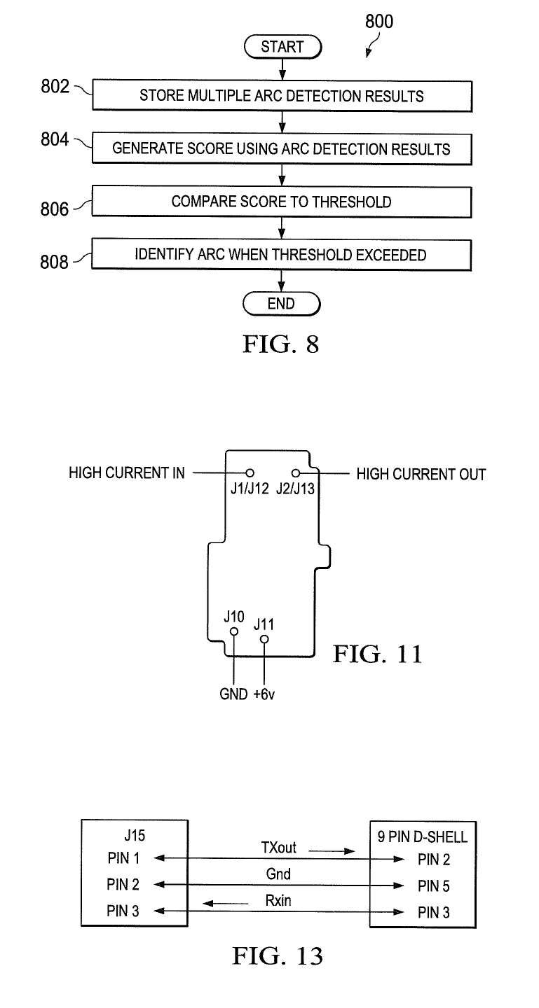

Steps 210-212 of FIG. 2 could occur as shown in FIG. 8, which illustrates an example method 800 for arc detection smoothing and threshold comparison. As shown in FIG. 8, to reduce the possibility of false triggers, multiple arc detection results are stored at step 802. This could include, for example, the arc detector 110 performing the method 700 multiple times to generate multiple arc detection results. The arc detection results could be stored in a rotating array that holds the last several results. For instance, the array could hold ten arc detection results, which amounts to 250 ms of arc data at a 40 Hz sampling rate. In the array, the oldest arc detection result is removed, and the newest arc detection result replaces it. The array can be cleared in an initialization routine.

A score is generated for the multiple arc detection results at step 804. This could include, for example, the arc detector 110 using the sum or average of the results in the array as the score of the arc detection routine. The score of the arc detection routine is compared to a threshold at step 806. This could include, for example, the arc detector 110 comparing the score to the Threshold parameter value. If the score exceeds the threshold, an arc is considered to be present at step 808.

Note that in the example arc detection routine shown in FIGS. 5 through 8, this technique allows an arc to be detected on one or multiple strings, and an annunciator or other indicator could be used to indicate that an arc has been detected. Also, while this technique uses fixed-point operations, floating-point or other operations could also be used. In addition, specific values described above (such as the number of bins, the number of bits, the number of FFT points, and no-arc versus arc scores) are for illustration only.

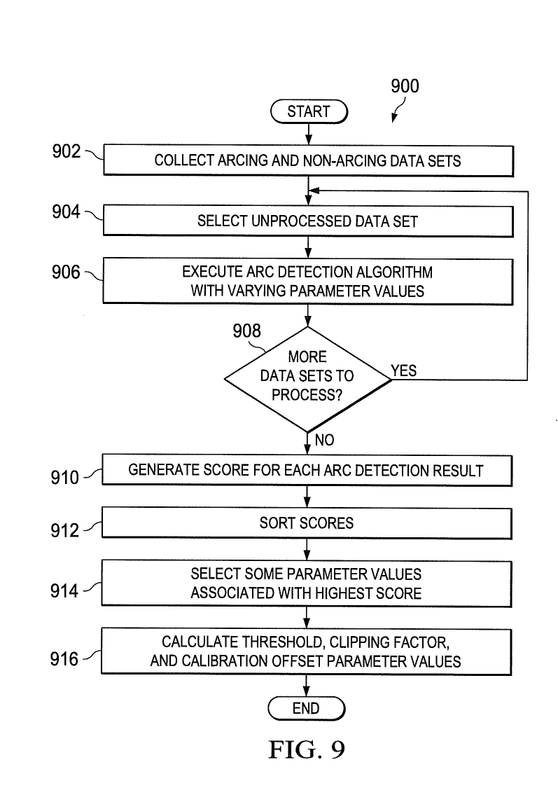

In the above-described arc detection technique, the values of the parameters in Table 1 could be selected in any suitable manner. The calculation of the parameter values in Table 1 could occur as shown in FIG. 9 (assuming the Number of Bands is already set to two). However, any other suitable technique could be used to identify the seven parameter values used here.

FIG. 9 illustrates an example method 900 for identifying parameter values for an arc detection technique. In this approach, the parameter values are identified using multiple measurements of known arcing and non-arcing conditions with multiple environments and equipment. A search then exhaustively evaluates various sets of parameter values to determine which parameter value set provides the best discrimination between arcing and non-arcing events.

As shown in FIG. 9, arcing and non-arcing data sample sets are collected at step 902. In some embodiments, each data set could include around 5,200 samples formatted as:
!start:<Firmware Rev>
sample (signed integer), sample number
. . .
!chksum: <summation of input values; as unsigned>
   These data sets could be captured using a circuit board installed in a high-voltage system, such as within a junction box 106 of the PV system 100. One example of the circuit board is described below. Data can be collected for many different permutations of PV or other high-voltage system settings, such as by collecting five or more distinct waveforms for each setting. These captured waveforms can be generated using the same hardware to ensure accurate results. An extension of .NTXT could be used for non-arcing waveform files, and an extension of .ATXT could be used for arcing waveform files. A laptop or other computing device connected via RS232 or other interface to a microcontroller can be used for data collection, and a WINDOWS HYPERTERMINAL program or other program can be used to save the data.

An unprocessed data set is selected at step 904, and the arc detection algorithm described above is executed using the selected data set while varying at least some of the algorithm's parameter values at step 906. The varied parameters could include Min Frequency, Max Frequency, Discard Factor, and Filter Weight. The Min Frequency could, for example, vary between 20 kHz and 90 kHz (in 5 kHz increments). The Max Frequency could, for example, vary between 35 kHz and 105 kHz (in 5 kHz increments). The Discard Factor could, for example, vary between values of 0.016, 0.031, 0.063, 0.125, 0.25, 0.5, 1, 2, 4, 8, 16, 32, and 64. The Filter Weight could, for example, vary between 0 and 0.7 (in 0.05 increments).

A determination is made whether other data sets remain to be processed at step 908. If so, the method 900 returns to step 904 to select another data set. In this way, the arc detection algorithm described above is executed for each data set while varying at least some of the parameter values.

A score is generated for each arc detection result determined by the arc detection algorithm at step 910. In general, any suitable score that can model how effectively a set of parameter values detected arc and non-arc conditions can be used. One example of a scoring equation could be:

[(Mean Arcing Value−1 Standard Deviation)/(Mean Non-Arcing Value+1 Standard Deviation)]−1

Another example of a scoring equation could be:

Min Arcing Value−(Mean Non-Arcing Value+1 Standard Deviation of Non-Arcing Values)

Here, Mean Arcing Value denotes the average value determined by the arc detection algorithm for all sets of arcing data using the same set of parameter values. Also, Mean Non-Arcing Value denotes the average value determined by the arc detection algorithm for all sets of non-arcing data using the same set of parameter values. In addition, Min Arcing Value denotes the smallest value determined by the arc detection algorithm for an arcing condition. Note that any other scoring algorithm could be used.

The scores are sorted at step 912, and the parameter values associated with the highest score are selected for use in the arc detection algorithm as deployed to monitor for electrical arcs at step 914. This could include, for example, identifying values for the Min Frequency, Max Frequency, Discard Factor, and Filter Weight parameters.

The Threshold, Clipping Factor, and Calibration Offset parameter values are calculated at step 916. For example, the Threshold value can be calculated as approximately five times the Mean Arcing Value. This value could be adjusted higher or lower to avoid false positives or false negatives. The Clipping Factor can be calculated as the maximum Arcing Value computed during execution of the arc detection algorithm plus ten. The Calibration Offset value can be calculated by setting this parameter value to compensate for board-to-board manufacturing tolerance shifts. This could be done by measuring a path gain at the center frequency of the analog filtering in the circuit board and determining a difference from a reference unit. The difference could then be stored in a non-volatile memory of the circuit board and used as the Calibration Offset. When the circuit board starts operation, it can retrieve the Calibration Offset value from the memory. In this way, the Calibration Offset parameter can be measured during production testing and is easily available by an automated testing procedure.

In particular embodiments, the method 900 could be implemented using a software tool. The software tool could automate the data collection process and the determination of the parameter values using the collected data. The software tool could also support default values for various parameters, such as the number of bands.

Although FIGS. 5 through 9 illustrate examples of implementations of various steps in the method 200 of FIG. 2, various changes may be made to FIGS. 5 through 9. For example, while shown as a series of steps, various steps in each figure could overlap, occur in parallel, occur in a different order, or occur multiple times. Also, the methods 500-900 could be used with any high-voltage system that can generate electrical arcs. Further, the description above represents one specific way to implement the method 200 and one specific way to determine parameter values for that implementation of the method 200. The method 200 could be implemented in any other suitable manner, and the parameter values could be determined in any other suitable manner. Moreover, as noted above, the arc detector 110 could be used with multiple PV strings or other portions of a system. In these embodiments, the arc detector 110 could perform the methods 500-900 for each PV string or other portion of the system, and data for each portion of the system could be handled separately (such as in separate localized history arrays). Beyond that, functions other than logarithmic functions could be applied during the method 700. In addition, the specific equations used here (such as for the scores and for the Threshold and Clipping Factor calculations) are for illustration only. Again, other techniques could be used to generate the scores or to calculate the parameter values.

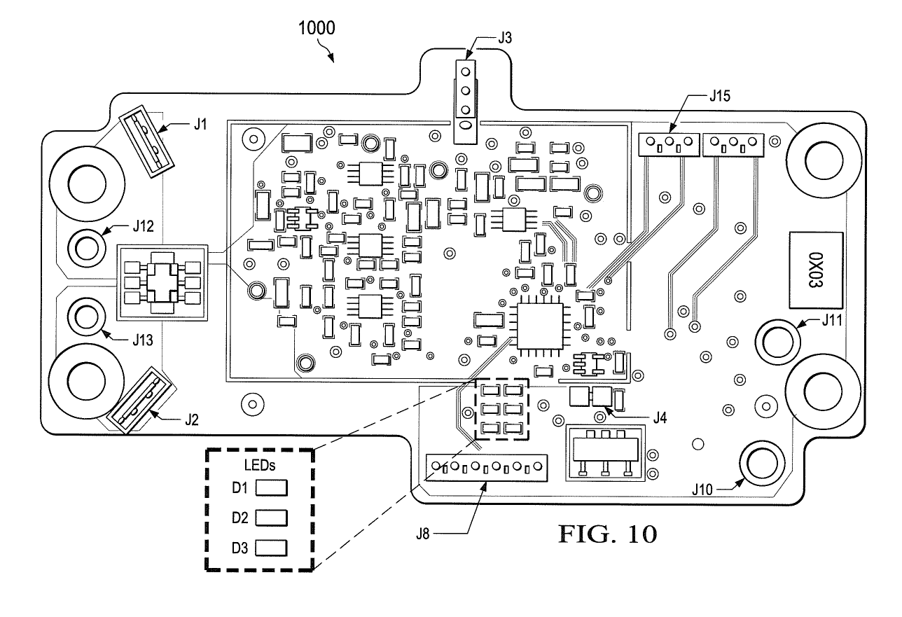

FIGS. 10 through 13 illustrate an example circuit board 1000 implementing an arc detector and related details in accordance with this disclosure. Note that the details shown here (such as maximum voltages/currents or types of connectors) are for illustration only.

As shown in FIG. 10, the circuit board 1000 provides arc detection capability for PV or other high-voltage systems, even in the presence of noisy environments and without requiring a specific learning mode. The circuit board 1000 can use the multi-band dynamic filtering routine described above.

The circuit board 1000 includes various connections used to couple the circuit board 1000 to a high-voltage system. Table 2 shows example connections and their uses.

TABLE 2

| Connection | Usage |
|---|---|
| J1/J12 | String Current A: J1 is a flag connector. J12 |
| | can use a banana plug. The maximum voltage |
| | can be 500 V. |
| J2/J13 | String Current B: J2 is a flag connector. J13 |
| | can use a banana plug. The maximum voltage |
| | can be 500 V. |
| J3 | VA Connection: A jumper between 5 V and VA may |
| | need to be present for operation. |
| J4 | Reset: Momentarily short these pins to reset |
| | the system. |
| J11/J8 pin 6 | Positive Supply: Provides a supply voltage |
| | V_{IN}, such as 5.4 V < V_{IN} < 12.5 V with >90 mA. J11 |
| | can use a banana plug. |
| J10/J8 pin 5 | Ground |
| J8 pin 1 | AUX1 Connection: This pin can go high when an |
| | arc has been detected. |
| J15 | RS232 Interface (See FIG. 13) |

An example connection of the circuit board 1000 to a high-voltage system is shown in FIG. 11. A high-current input/output is coupled to connection J1 or J12, and a high-current input/output is coupled to connection J2 or J13. Connection J10 is coupled to ground, and connection J11 is coupled to a positive supply voltage V_{IN} (+6V in this example). Note that a battery (such as a 9V battery) can be used to supply power to the circuit board 1000 for several hours. The connection J15 can optionally be coupled to an RS232 cable. In particular embodiments, up to 15A of current can be sent through the high-current input and output (even if the circuit board 1000 is not powered on), and current can flow in either direction. Also, in particular embodiments, the maximum voltage of the circuit board 1000 could be 500V. While the circuit board 1000 could be coupled on the high-voltage side of a PV array or other high-voltage system, it may be safer to couple the circuit board 1000 to the low-voltage side.

Three LEDs in the circuit board 1000 can operate as follows. Upon power-up, red LED D1 and green LED D3 could turn on for approximately two seconds, after which LED D1 turns off and green LED D2 turns on. LED D2 could then remain on, while LED D3 slowly blinks (such as at a two-second interval) as the arc detection routine is executed. If an arc is detected, the LED D1 could turn on. In a demonstration mode, a detected arc is automatically cleared, LED D1 turns off, and arc detection resumes after four seconds. In actual usage, a detected arc is latched, and a manual reset may be needed to reset the system for safety purposes.

FIG. 12 shows an example test setup 1200 that can be used to evaluate the arc detection functionality and to collect data during arcing and non-arcing conditions (for use in determining parameter values). As shown in FIG. 12, the setup 1200 includes multiple PV panels 1202, which can be arranged in any suitable configuration. The PV panels 1202 are coupled to an inverter 1204. An arc generator 1206 is used to physically create an arc in the setup 1200, allowing the collection of data during known arcing conditions. An arc can be generated in any number of ways. A knife switch can be an effective, simple, and safe method to generate an arc. An arc detector 1208 (such as the circuit board 1000) is coupled to the string of PV panels 1202. The arc detector 1208 can detect arcs no matter where along the string of PV panels 1202 it is connected, although it may be recommended to place the arc detector 1208 on the grounded conductor side of the string if possible.

As noted above, the circuit board 1000 can output an arc detection status via an RS232 interface. For example, the circuit board 1000 can periodically issue a message indicating either “no arc detected” or “arc detected” as appropriate. In some embodiments, a custom interface cable is used to support this functionality. An example of the custom interface cable is shown in FIG. 13. As shown in FIG. 13, pin 1 of the connection J15 can be a “transmit out” pin and can couple to pin 2 of a 9-pin D-shell cable. Pin 2 of the connection J15 can be a ground pin and can couple to pin 5 of the 9-pin D-shell cable. Pin 3 of the connection J15 can be a “receive in” pin and can couple to pin 3 of the 9-pin D-shell cable. Note, however, that other RS232 cables or other types of connections could be used with the circuit board 1000.

A terminal program or other program can be used to collect data from the circuit board 1000. This could be done, for example, during data collection in step 902 of FIG. 9. Any suitable program could be used, such as WINDOWS HYPERTERMINAL. Once the program starts, a name for the connection can be provided (such as “ArcDetectConnect”), and the appropriate COM port is selected. In particular embodiments, the port settings can be 115200 bits per second, eight data bits, no parity, one stop bit, and no flow control. When connected and powered up, the circuit board 1000 can transmit a version information header and then transmit either an “arc searching” or “arc detected” message on its console port. The circuit board 1000 can further be configured to receive instructions for changing various parameters (such as Min Frequency, Max Frequency or Bandwidth, Discard Factor, etc.) and other behavior (such as disabling auto-clear of arc detections and support for a test mode).

Obviously, caution should be taken when generating arcs in the setup 1200. High voltages can pose a lethal hazard, and incandescent metal sparks and open flames can be present. Therefore, safety gear (including eye/face protection and electrical gloves rated for the appropriate electrical conditions) and any other equipment appropriate for the conditions can be used.

Although FIGS. 10 through 13 illustrate one example of a circuit board 1000 implementing an arc detector and related details, various changes may be made to FIGS. 10 through 13. For example, the arc detector 110 could be implemented in any other suitable manner, such as by using a circuit board with other input/output connections or other electrical components or by using a processing device that executes software/firmware instructions. As particular examples, the functionality of the circuit board 1000 could be implemented on a single integrated circuit chip or a combination of chips, such as a DSP and a microcontroller. In addition, the circuit board 1000 or other implementation of the arc detector 110 could be used with multiple PV strings or other portions of a system. In these embodiments, the circuit board 1000 or other implementation of the arc detector 110 could include connections to multiple portions of the system, the arc detection algorithm can be executed for each portion of the system, and data can be collected for each portion of the system.

In some embodiments, various functions described above are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

It may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
receiving data associated with operation of a high-voltage system;
determining a power spectrum associated with the data;
dividing the power spectrum into multiple bands;
filtering one or more interfering signals from the power spectrum within the bands; and
generating an arc detection result indicative of whether an electrical arc is present in the high-voltage system using remaining signals within the bands.

2. The method of claim 1, wherein filtering the one or more interfering signals comprises:
identifying one or more peak values at one or more frequencies in each of the bands; and
at least partially reducing a magnitude of the power spectrum at each of the one or more frequencies in each of the bands.

3. The method of claim 2, wherein generating the arc detection result comprises:
summing magnitudes of the remaining signals in each of the bands to generate a summation for each of the bands; and
applying at least one scaling factor to at least one of the summations to generate at least one scaled summation.

4. The method of claim 3, wherein generating the arc detection result further comprises:
generating a total sum of the summations or scaled summations;
applying a function to the total sum to generate a function value; and
applying at least one correction or compensation to the function value to generate the arc detection result.

5. The method of claim 4, wherein applying the at least one correction or compensation comprises:
applying at least one correction to the function value to compensate for time domain processing of the data; and
applying at least one calibration factor to the function value to compensate for device variations.

6. The method of claim 1, further comprising:
applying time domain processing to the data to generate processed data before determining the power spectrum; and
transforming the processed data into a frequency domain to generate frequency domain data before determining the power spectrum.

7. The method of claim 6, wherein applying the time domain processing comprises:
identifying a range and an average value of the data;
subtracting the average value from the data to generate resulting data;
applying a Hanning window to the resulting data to generate windowed data; and
dynamically scaling the windowed data based on the range.

8. The method of claim 6, wherein determining the power spectrum comprises:
converting the frequency domain data into the power spectrum.

9. The method of claim 1, further comprising:
generating a score using multiple arc detection results; and
determining that an electrical arc is present when the score exceeds a threshold.

10. An apparatus comprising:
at least one interface configured to receive data associated with operation of a high-voltage system; and
at least one processing unit configured to determine a power spectrum associated with the data, divide the power spectrum into multiple bands, filter one or more interfering signals from the power spectrum within the bands, and generate an arc detection result indicative of whether an electrical arc is present in the high-voltage system using remaining signals within the bands.

11. The apparatus of claim 10, wherein the at least one processing unit is configured to filter the one or more interfering signals by:
identifying one or more peak values at one or more frequencies in each of the bands; and
at least partially reducing a magnitude of the power spectrum at each of the one or more frequencies in each of the bands.

12. The apparatus of claim 11, wherein the at least one processing unit is configured to generate the arc detection result by:
summing magnitudes of the remaining signals in each of the bands to generate a summation for each of the bands; and
applying at least one scaling factor to at least one of the summations to generate at least one scaled summation.

13. The apparatus of claim 12, wherein the at least one processing unit is configured to generate the arc detection result further by:
generating a total sum of the summations or scaled summations;
applying a function to the total sum to generate a function value; and
applying at least one correction or compensation to the function value to generate the arc detection result.

14. The apparatus of claim 10, wherein the at least one processing unit is further configured to:
apply time domain processing to the data to generate processed data; and
transform the processed data into a frequency domain to generate frequency domain data.

15. The apparatus of claim 14, wherein the at least one processing unit is configured to apply the time domain processing by:
identifying a range and an average value of the data;
subtracting the average value from the data to generate resulting data;
applying a Hanning window to the resulting data to generate windowed data; and
dynamically scaling the windowed data based on the range.

16. The apparatus of claim 14, wherein the at least one processing unit is configured to determine the power spectrum by converting the frequency domain data into the power spectrum.

17. The apparatus of claim 10, wherein the at least one processing unit is further configured to:
generate a score using multiple arc detection results; and
determine that an electrical arc is present when the score exceeds a threshold.

18. A non-transitory computer readable medium embodying a computer program, the computer program comprising computer readable program code for:
receiving data associated with operation of a high-voltage system;
determining a power spectrum associated with the data;
dividing the power spectrum into multiple bands;
filtering one or more interfering signals from the power spectrum within the bands; and
generating an arc detection result indicative of whether an electrical arc is present in the high-voltage system using remaining signals within the bands.

19. The computer readable medium of claim 18, wherein the computer readable program code for filtering the one or more interfering signals and the computer readable program code for generating the arc detection result comprise computer readable program code for:
identifying one or more peak values at one or more frequencies in each of the bands;
at least partially reducing a magnitude of the power spectrum at each of the one or more frequencies in each of the bands;
summing magnitudes of the remaining signals in each of the bands to generate a summation for each of the bands;
applying at least one scaling factor to at least one of the summations to generate at least one scaled summation;
generating a total sum of the summations or scaled summations;
applying a function to the total sum to generate a function value; and
applying at least one correction or compensation to the function value to generate the arc detection result.

20. The computer readable medium of claim 18, wherein:
the computer program further comprises computer readable program code for applying time domain processing to the data to generate processed data, the time domain processing comprising:
identifying a range and an average value of the data;
subtracting the average value from the data to generate resulting data;
applying a Hanning window to the resulting data to generate windowed data; and
dynamically scaling the windowed data based on the range;
the computer program further comprises computer readable program code for transforming the processed data into a frequency domain to generate frequency domain data; and
the computer readable program code for determining the power spectrum comprises computer readable program code for converting the frequency domain data into the power spectrum.
